(19) United States
(12) Patent Application Publication
(10) Pub. No.: US 2007/0178410 A1
(43) Pub. Date: Aug. 2, 2007

(54) Method of forming three-dimensional lithographic pattern

(75) Inventors: Chiang-Lin Shih, Taipei (TW); Chih-Li Chen, Taipei (TW)

Correspondence Address: INGRASSIA FISHER & LORENZ, P.C., 7150 E. CAMELBACK, STE. 325, SCOTTSDALE, AZ, 85251, US

(73) Assignee: United Epitaxy Company, Ltd.

(21) Appl. No.: 11/453,764

(22) Filed: Jun. 14, 2006

(30) Foreign Application Priority Data
Jan. 27, 2006 (TW) 95103668

(51) Int. Cl. G03F 7/20

(52) U.S. Cl. 430/311; 430/394

(57) ABSTRACT

A method of forming a three-dimensional lithographic pattern is provided. The method includes providing a substrate. A first photoresist layer is formed on the substrate. The first photoresist layer corresponds to a first exposure removal dose. A second photoresist layer is formed on the first photoresist layer. The second photoresist layer corresponds to a second exposure removal dose, which is different from the first exposure removal dose. A reticle with multiple regions of different light transmittances is provided. Through the reticle, the first and second photoresist layers are exposed to form a first removable region in the first photoresist layer and a second removable region in the second photoresist layer. The second removable region is different from the first removable region. The first and second photoresist layers are then developed to remove the first and second removable regions.

### FIELD OF INVENTION

The present invention generally relates to a method of forming a semiconductor device, and more particularly, to a method of forming a three-dimensional lithographic pattern for a semiconductor device.

### BACKGROUND OF THE INVENTION

The fabrication of semiconductor devices generally repeatedly performs a series of processes including lithography, etch, deposition, doping, etc on a semiconductor wafer to form layer-stacked integrated circuits. Therefore, the formation of electrical contacts or connections between every layer is one of important processes during the fabrication of integrated circuit devices. As the device size shrinks and the integration density increases, however, the process window and the test limit become more and more rigorous, which particularly seriously influence the formation of the integrated circuit.

A three-dimensional structure, such as a dual damascene, a bottle-like capacitor, or any other three-dimensional device structure as appropriate, is generally required for the manufacture of a semiconductor device. A conventional method of forming a three-dimensional structure generally repeats steps of depositing, coating, exposing, developing, etc. so as to form a desired pattern in each layer respectively. For example, a dual damascene process is typically classified as a via first process flow and a trench first process flow. However, no matter the via first process flow or the trench first process flow is adopted, the etch process and the lithography process are repeatedly performed on each layer so as to define a via and a trench, respectively. For example, the conventional method typically performs two lithography processes; one defines the via, and the other defines the trench. Accordingly, the alignment of these two individual lithographic processes becomes critical and results in the complication of the manufacture process flow of the integrated circuit. Once the misalignment is occurred, the process of rework should be performed, and more seriously, the wafer may be fatally damaged.

Therefore, there is a need to provide a method of forming a three-dimensional lithographic pattern, which can simplify the process flow, alleviate the alignment issue, reduce the production cost, and increase the throughput.

### SUMMARY OF THE INVENTION

One aspect of the present invention is to provide a method of forming a three-dimensional lithographic pattern, which implements a reticle with multiple regions of different light transmittances and forms a three-dimensional pattern in a single exposure step.

Another aspect of the present invention is to provide a method of forming a dual damascene pattern, which implements multiple layers of photoresist and one reticle to form the desired dual damascene pattern in a single exposure step. In comparison with the conventional technologies, the present invention can simplify the process flow, alleviate the alignment issue, reduce the production cost, and increase the throughput.

In one embodiment of the present invention, a method of forming a three-dimensional lithographic pattern, such as a dual damascene pattern or a bottle-like pattern, is provided. The method includes a step of providing a substrate. A first photoresist layer is formed on the substrate. The first photoresist layer corresponds to a first exposure removal dose. Then, a second photoresist layer is formed on the first photoresist layer. The second photoresist layer corresponds to a second exposure removal dose, which is different from the first exposure removal dose. A reticle with multiple regions of different light transmittances is then provided. Through the multiple regions of different light transmittances of the reticle, the first photoresist layer and the second photoresist layer are exposed so as to form a first removable region in the first photoresist layer and a second removable region in the second photoresist layer, respectively. The second removable region is different from the first removable region. Then, the first photoresist layer and the second photoresist layer are developed to remove the first removable region and the second removable region.

In an exemplary embodiment, the reticle includes a transparent substrate, a high light transmittance layer, and an opaque layer to constitute the multiple regions of different light transmittances. In an exemplary embodiment, the first exposure removal dose is higher than the second exposure removal dose. The step of exposing includes a step of modulate the exposure energy through one of the multiple regions of different light transmittance so that the modulated energy is substantially equal to or higher than the second exposure removal dose and less than the first exposure removal dose to form the second removable region substantially only in the second photoresist layer.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates a cross-sectional view of a substrate with two photoresist layers in accordance with one embodiment of the present invention;

FIG. 2A illustrates a cross-sectional view of exposing the substrate of FIG. 1 through a reticle in accordance with one embodiment of the present invention;

FIG. 2B illustrates a cross-sectional view of removing removable regions of FIG. 2A;

FIG. 3A illustrates a cross-sectional view of exposing the substrate of FIG. 1 through a reticle in accordance with another embodiment of the present invention; and

FIG. 3B illustrates a cross-sectional view of removing removable regions of FIG. 3A.

### DETAILED DESCRIPTION OF THE INVENTION

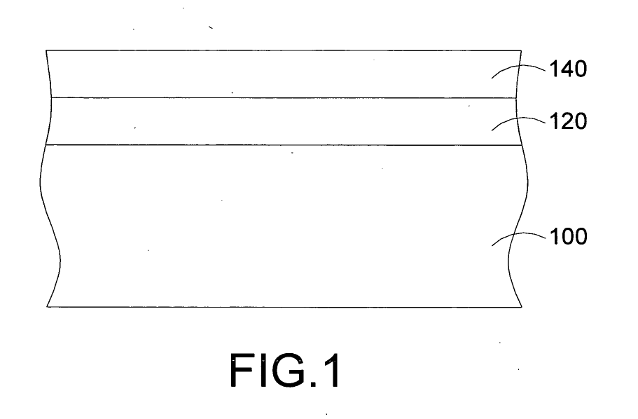

The present invention discloses a method of forming a three-dimensional lithographic pattern, which implements multiple layers of photoresist and a single reticle, in one exposure step, to form different removable regions in each photoresist layer. As a result, the frequency of a substrate uploading to or offloading from a lithography equipment is reduced and the alignment issue is alleviated. Accordingly, the production cost is reduced, and the throughput is increased. FIGS. 1 to 3B illustrate preferred embodiments of the present invention.

Referring to FIG. 1, in one embodiment, the present invention provides a method of forming a three-dimensional lithographic pattern. The three-dimensional lithographic pattern can be, for example, a dual damascene pattern, or a bottle-like pattern. The method includes a step of providing a substrate 100, which can be a semiconductor substrate or an incomplete semiconductor device. The semiconductor substrate can be, for example, but not limit to a silicon (Si) substrate, a germanium (Ge) substrate, a semiconductor on insulator (SOI), a silicon germanium on insulator (SGeOI). The incomplete semiconductor device can be any substrate during the process flow of manufacturing a semiconductor device, for example, a substrate to be formed with a interconnect or any substrate to be formed with a three-dimensional pattern therein as appropriate.

A first photoresist layer 120 is then formed on the substrate 100. The first photoresist layer 120 corresponds to a first exposure removal dose. It is noted that the exposure removal dose represents an exposure energy required to make the photoresist, after the exposure step, become substantially removable in a development process. In other words, when the photoresist is exposed with an exposure energy smaller than the exposure removal dose, the exposed photoresist region remains irremovable in the development step, and the desired pattern cannot be formed. When the photoresist layer is exposed with an exposure energy substantially equal to or higher than the exposure removal dose, the exposed photoresist becomes removable in the development step, and a desired pattern can be formed. A second photoresist layer 140 is then formed on the first photoresist layer 120. The second photoresist layer 140 corresponds to a second exposure removal dose, which is different from the first exposure removal dose. In an exemplary embodiment, the first exposure removal dose is higher than the second exposure removal dose. In other words, the first photoresist layer 120 requires an energy higher than that of the second photoresist layer 140 so as to be removed in a development process after the exposure step. It is noted that the present invention is applicable to a positive photoresist or a negative photoresist. In this embodiment, positive photoresists are illustrated.

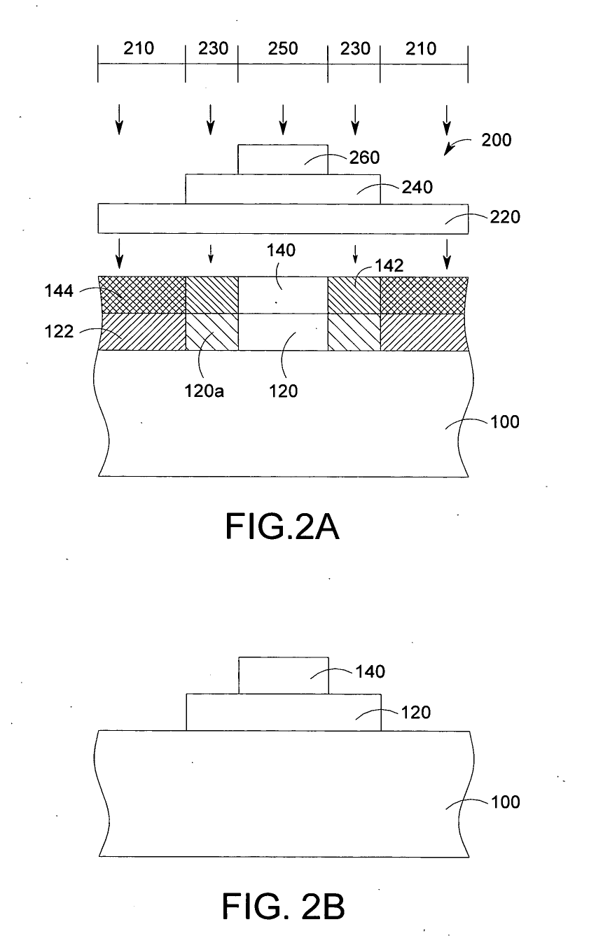

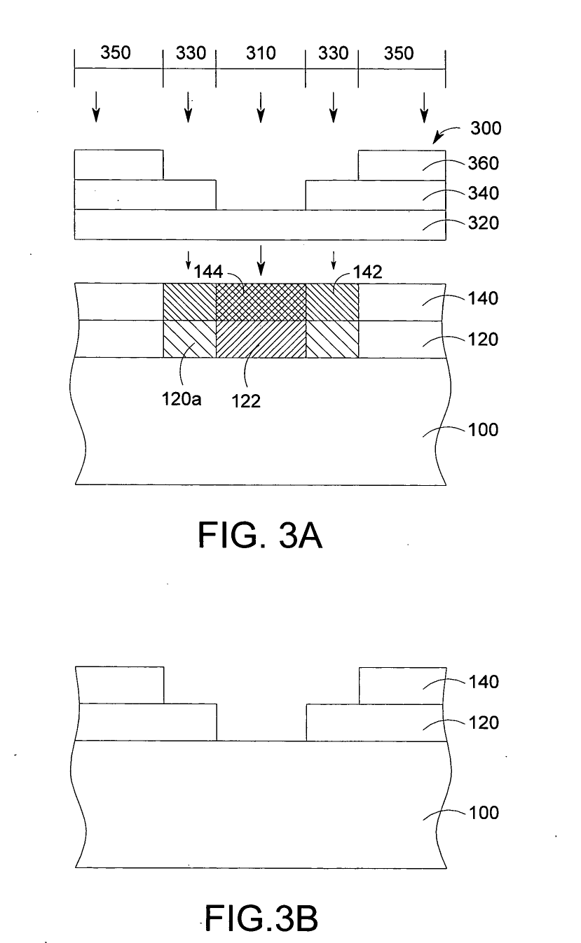

Referring to FIG. 2A, a reticle 200 with multiple regions of different light transmittances (210, 230, 250) is provided. For example, the reticle 200 includes a transparent substrate 220, a high light transmittance layer 240, and an opaque layer 260 constituting the multiple regions of different light transmittances. The light transmittance is substantially 100% for the transparent substrate 220 and 0 for the opaque layer 260. The light transmittance for the high transmittance layer 240 is in a range from 0 to 100%, which is preferably selected based on the photoresist implemented. Therefore, the light transmittance is substantially 100% for region 210, 0 for region 250, and between 0 to 100% for region 230. The transparent substrate 220 includes, for example, a glass substrate, a quartz substrate, or any transparent substrate for a conventional reticle as appropriate. The opaque layer 260 can be a metal layer, such as a chromium layer. The light transmittance of the high light transmittance layer 240 is preferably selected so that an exposure energy is modulated to be substantially between the first exposure removal dose and the second exposure removal dose. The high light transmittance layer 240 and the opaque layer 260 are patterned and arranged on the transparent substrate 220 based on the design requirement of a desired three-dimensional pattern. As shown in FIGS. 2A and 3A, the reticle 200 and the reticle 300 are utilized to form the lithographic patterns as shown in FIGS. 2B and 3B, respectively. It is noted that though the present invention is illustrated in cross-sectional views, the patterns of the reticles can vary with the design need of different devices and are not limited to the embodiments.

Through the multiple regions of different light transmittances (210, 230, 250) of the reticle 200, the first photoresist layer 120 and the second photoresist layer 140 are exposed so as to form a first removable region 122 in the first photoresist layer 120 corresponding to the region 210, a second removable region 142 in the second photoresist layer 140 corresponding to the region 250, and a removal region 144 in the second photoresist layer 120 corresponding to the region 230, respectively.

For example, in this exemplary embodiment, the step of exposing includes a step of exposing with an exposure energy substantially equal to or higher than the first exposure removal dose. Through portions of the transparent substrate 220, which is uncovered by the high light transmittance layer 240 and the opaque layer 260, the first removable region 122 is formed in the first photoresist layer 120. At the same time, through one of the multiple regions, which is portions of the high light transmittance layer 240 uncovered by the opaque layer 260 (i.e. region 230), the exposure energy is modulated. The modulated energy is substantially equal to or higher than the second exposure removal dose and less than the first exposure removal dose. Therefore, during the exposure, the modulated energy is configured to form the second removable region 142 substantially only in the second photoresist layer 140. In other words, through the reticle 200 with the arrangement of the opaque layer 260 and the high light transmittance layer 240, the regions of the first photoresist layer 120 and the second photoresist layer 140 corresponding to the region 250 are not exposed with the exposure energy. However, the region of the first photoresist layer 120 corresponding to the region 210 is fully exposed with the exposure energy and transformed into the first removable region 122, while the region of the second photoresist layer 140 corresponding to the first removable region 122 is also fully exposed with the exposure energy and transformed into a removable region 144. Moreover, due to the modulation of the high light transmittance layer 240, the region of the second photoresist layer corresponding to the region 230 is exposed with the modulated energy and transformed into to the second removable region 142. That is, the second removable region 142 is formed substantially only in the second photoresist layer 140. It is noted that though the region of the first photoresist layer 120 corresponding to the removable region 142 (i.e. the region 120a) is exposed with the modulated energy, due to the lack of sufficient energy (i.e. less than the first exposure removal dose), the exposed region 120a cannot be removed in a subsequent development step.

It is noted that in one embodiment, when the difference between the first exposure removal dose and the second exposure removal dose is small, the high light transmittance layer 240 is preferably selected to modulate the exposure energy substantially equal to the second exposure removal dose. As such, it can prevent an undesired pattern from forming in the first photoresist layer 120 due to the influence of noise. Alternatively, when the difference between the first exposure removal dose and the second removal dose is significant, the high light transmittance layer is preferably selected to modulate the exposure energy slightly higher than the second exposure removal dose so as to ensure that the desired removable region 142 in the second photoresist layer 140 is fully exposed, and therefore, to enhance the resolution.

Referring to FIG. 2B, the first photoresist layer 120 and the second photoresist layer 140 are then developed so as to remove the first removable region 122, the second removable region 142, and the removable region 144 so as to form the three-dimensional pattern as shown in FIG. 2B.

Referring to FIG. 3A, in another embodiment of the present invention, a different reticle 300 cooperated with dual layers of photoresist are implemented to form a lithographic pattern in one exposure step as illustrated in FIG. 3B. As shown in FIG. 3A, a high light transmittance layer 340 and an opaque layer 360 designed based on the device need are patterned and arranged on a transparent substrate 320 so as to form the reticle 300. In this embodiment, through multiple regions of different light transmittances (310, 330, 350) of the reticle 300, the first photoresist layer 120 and the second photoresist layer 140 are exposed to form a first removable region 122 in the first photoresist layer 120 corresponding to the region 310 and a second removable region 142 and a removable region 144 in the second photoresist layer 120 corresponding to the region 330 and the region 310 respectively. The first photoresist layer 120 and the second photoresist layer 140 are then developed to remove the first removable region 122, the second removable region 142, and the removable region 144, as shown in FIG. 3B. Similarly, though the region of the first photoresist layer 120 corresponding to the removable region 142 (i.e. the region 120a) is exposed with the modulated energy, due to the lack of sufficient energy (i.e. less than the first exposure removal dose), the exposed region 120a cannot be removed in a subsequent development step. The present invention implements multiple layers of photoresist and multiple regions of different light transmittances of reticle to form a desired three-dimensional pattern in one exposure step. In comparison with conventional technologies, the present invention reduces the frequency of a substrate uploading to or offloading from a lithography equipment, resulting in the simplification of the process flow, the elimination of misalignment, the reduction of the production cost, and the increase in the throughput.

It is noted that the selection of the first and the second photoresist layers preferably respectively corresponds exposure removal doses with significant difference so as to minimize the influence of noise and to facilitate the manipulation of the exposure energy and the feasibility of the high light transmittance layer. Furthermore, the method includes a step of transferring the three-dimensional pattern, such as a dual damascene pattern, into the substrate by using the patterned photoresist as a mask to etch the substrate.

Although specific embodiments have been illustrated and described, it will be obvious to those skilled in the art that various modifications may be made without departing from what is intended to be limited solely by the appended claims.

What is claimed is:

1. A method of forming a three-dimensional lithographic pattern, comprising:
providing a substrate;
forming a first photoresist layer on said substrate, said first photoresist layer corresponding to a first exposure removal dose;
forming a second photoresist layer on said first photoresist layer, said second photoresist layer corresponding to a second exposure removal dose different from said first exposure removal dose;
providing a reticle with multiple regions of different light transmittances;
through said multiple regions of different light transmittances of said reticle, exposing said first photoresist layer and said second photoresist layer so as to form a first removable region in said first photoresist layer and a second removable region in said second photoresist layer, respectively, wherein said second removable region is different from said first removable region; and
developing said first photoresist layer and said second photoresist layer so as to remove said first removable region and said second removable region.

2. The method of claim 1, wherein said substrate comprises a semiconductor substrate or an incomplete semiconductor device.

3. The method of claim 1, wherein said reticle comprises a transparent substrate, a high light transmittance layer, and an opaque layer to constitute said multiple regions of different light transmittances.

4. The method of claim 1, wherein said first exposure removal dose is higher than said second exposure removal dose.

5. The method of claim 4, wherein said step of exposing comprises a step of exposing with an exposure energy substantially equal to or higher than said first exposure removal dose.

6. The method of claim 5, wherein said step of exposing comprises a step of modulate said exposure energy through one of said multiple regions of different light transmittance so that said modulated energy is substantially equal to or higher than said second exposure removal dose and less than said first exposure removal dose to form said second removable region substantially only in said second photoresist layer.

7. The method of claim 1, wherein said step of exposing comprises forming a removable region in said second photoresist layer, and said removable region overlaps said first removable region and is adjacent to said second removable region.

8. The method of claim 7, wherein said first removable region, said second removable region, and said removable region constitute a three-dimensional pattern comprising a dual damascene pattern or a bottle-like pattern.

9. A method of forming a dual damascene pattern, comprising:
providing a substrate;
forming a first photoresist layer on said substrate, said first photoresist layer corresponding to a first exposure removal dose;
forming a second photoresist layer on said first photoresist layer, said second photoresist layer corresponding to a second exposure removal dose smaller than said first exposure removal dose;
providing a reticle with multiple regions of different light transmittances;
through said reticle, exposing said first photoresist layer and said second photoresist layer so as to form a first removable region in said first photoresist layer and a removable region in said second photoresist layer through one of said multiple regions of different light transmittances and to form a second removable region substantially only in said second photoresist layer through another one of said multiple regions of different light transmittances, respectively;
developing said first photoresist layer and said second photoresist layer so as to remove said first removable region, said second removable region, and said removable region to form a patterned photoresist; and
etching said substrate to form said patterned dual damascene pattern in said substrate by using said patterned photoresist as a mask.

10. The method of claim 9, wherein said substrate comprise a semiconductor substrate or an incomplete semiconductor device.

11. The method of claim 9, wherein said reticle comprises a transparent substrate, a high light transmittance layer, and an opaque layer to constitute said multiple regions of different light transmittances.

12. The method of claim 9, wherein said step of exposing comprises a step of exposing with an exposure energy substantially equal to or higher than said first exposure removal dose.

13. The method of claim 12, wherein said step of exposing comprises a step of modulate said exposure energy through said another one of said multiple regions of different light transmittance so that said modulated energy is substantially equal to or higher than said second exposure removal dose and less than said first exposure removal dose to form said second removable region substantially only in said second photoresist layer.

14. The method of claim 9, wherein said removable region overlaps said first removable region and is adjacent to said second removable region.
